(19) United States
(12) Patent Application Publication
(10) Pub. No.: US 2024/0033867 A1
(43) Pub. Date: Feb. 1, 2024

(54) CUTTING BLADE STOCK APPARATUS

(71) Applicant: DISCO CORPORATION, Tokyo (JP)

(72) Inventors: Aimi YAMATO, Tokyo (JP); Satoshi OHKAWARA, Tokyo (JP); Masaaki HIYAMA, Tokyo (JP); Takuto KAMIMURA, Tokyo (JP)

(21) Appl. No.: 18/351,679

(22) Filed: Jul. 13, 2023

(30) Foreign Application Priority Data
Jul. 28, 2022 (JP) 2022-120147

(51) Int. Cl. B23Q 3/155; B26D 7/00

(52) U.S. Cl. CPC B23Q 3/15526; B26D 7/00; B23Q 3/15546; B23Q 2003/15537

(57) ABSTRACT

There is provided a cutting blade stock apparatus that stocks multiple cutting blades used for cutting of a workpiece. The cutting blade stock apparatus includes a case placement stage at which a case capable of housing the cutting blade is placed, a case conveying unit that conveys the case placed at the case placement stage, a shelf that supports and stocks the case conveyed by the case conveying unit, a case identification information reading unit that reads case identification information given to the case, a case opening unit that opens the case, a cutting blade conveying unit that carries out the cutting blade from the case opened by the case opening unit, and an input interface to which information that specifies the cutting blade to be carried out by the cutting blade conveying unit is input.

### BACKGROUND OF THE INVENTION

### Field of the Invention

The present invention relates to a cutting blade stock apparatus that stocks multiple cutting blades used for cutting of a workpiece.

### Description of the Related Art

Device chips including a device are manufactured by dividing a wafer in which multiple devices are formed to dice the wafer into individual pieces. Further, a package substrate is obtained by mounting multiple device chips on a base substrate and coating the mounted device chips with a sealing material (mold resin) composed of a resin. Package devices including multiple device chips made into a package are manufactured by dividing this package substrate to dice it into individual pieces. The device chips and the package devices are incorporated into various pieces of electronic equipment such as mobile phones and personal computers.

A cutting apparatus is used for the dividing of a workpiece such as the wafer or the package substrate (refer to Japanese Patent Laid-open No. H11-77461). The cutting apparatus includes a chuck table that holds the workpiece and a cutting unit that executes cutting processing for the workpiece. A spindle is incorporated in the cutting unit and an annular cutting blade is mounted on a tip part of the spindle. The workpiece is cut and divided by holding the workpiece by the chuck table and causing the cutting blade to cut into the workpiece while rotating the cutting blade.

### SUMMARY OF THE INVENTION

The cutting blade mounted in the cutting apparatus is replaced by another cutting blade at a predetermined timing. For example, the kind of cutting blade used for cutting of a workpiece is selected according to the kind of workpiece and a processing condition. Thus, replacement of the cutting blade is executed every time the kind of workpiece or the processing condition is changed. Further, the cutting blade gradually wears due to cutting of the workpiece. Therefore, when the amount of wear of the cutting blade exceeds a certain amount, the cutting blade that has been used is replaced by a cutting blade as a new product.

Cutting blades for replacement are collectively stocked at a predetermined storage site such as a storeroom. Moreover, at the time of replacement of the cutting blade, a worker selects and takes out the cutting blade suitable for the kind of workpiece and the processing condition at the storage site of the cutting blades, and mounts the cutting blade in the cutting apparatus. However, a large number of kinds of cutting blades are stored at the storage site and complicated inventory management is necessary. Further, when many kinds of cutting blades are stocked at the storage site, there is a possibility that the worker selects an incorrect kind of cutting blade when taking out a predetermined cutting blade from the storage site. In this case, processing of a workpiece is executed with an unintended kind of cutting blade and troubles such as processing failure and breakage of the cutting blade possibly occur.

The present invention is what is made in view of such a problem, and intends to provide a cutting blade stock apparatus that allows simplification of management of cutting blades.

In accordance with an aspect of the present invention, there is provided a cutting blade stock apparatus that stocks a plurality of cutting blades used for cutting of a workpiece. The cutting blade stock apparatus includes a case placement stage at which a case capable of housing the cutting blade is placed, a case conveying unit that conveys the case placed at the case placement stage, a shelf that supports and stocks the case conveyed by the case conveying unit, a case identification information reading unit that reads case identification information given to the case, a case opening unit that opens the case, a cutting blade conveying unit that carries out the cutting blade from the case opened by the case opening unit, and an input interface to which information that specifies the cutting blade to be carried out by the cutting blade conveying unit is input.

Preferably, the case conveying unit includes a belt conveyor, a case moving part that moves the case placed at the case placement stage to the belt conveyor, a temporary placement region in which the case conveyed by the belt conveyor is temporarily placed, and a case conveying part that conveys the case temporarily placed in the temporary placement region to the shelf. Further, preferably, the case identification information reading unit is mounted on the case conveying part.

Moreover, preferably, the cutting blade conveying unit carries in the cutting blade that has been used. Further, preferably, the cutting blade conveying unit carries in the cutting blade that has been used through a conveyance port. Moreover, preferably, the cutting blade conveying unit carries out the specified cutting blade through the conveyance port.

Further, preferably, the cutting blade stock apparatus further includes a blade identification information reading unit that reads blade identification information given to the cutting blade.

Moreover, preferably, the cutting blade stock apparatus includes a plurality of the case placement stages. Further, preferably, the case is allowed to be placed at an optional position in the case placement stage.

Moreover, preferably, the cutting blade stock apparatus further includes a plurality of dedicated case placement stages at which a predetermined kind of the case is placed and a display part. The display part indicates the dedicated case placement stage at which the case is to be placed on a basis of the case identification information. Further, preferably, the display part is a display or an indicator light.

When the information that specifies the cutting blade is input, the cutting blade stock apparatus according to the aspect of the present invention carries out the specified cutting blade from the case stocked on the shelf. Thus, the worker does not need to search for and pick up the specific cutting blade from a large number of cutting blades by oneself. Due to this, management of the cutting blades is simplified and a mistake in taking the cutting blade is prevented, so that the occurrence of processing failure and breakage of the cutting blade due to processing of the workpiece by the incorrect cutting blade can be avoided.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a cutting blade stock apparatus;

FIG. 2 is a perspective view illustrating a case that can house a cutting blade;

FIG. 3 is a perspective view illustrating the cutting blade stock apparatus in the state in which the cases are placed in a case placement stage;

FIG. 4 is a perspective view illustrating constituent elements of the cutting blade stock apparatus;

FIG. 5A is a perspective view illustrating a case transferring part;

FIG. 5B is a perspective view illustrating the case transferring part that transfers the cases;

FIG. 6 is a perspective view illustrating a case conveying part;

FIG. 7 is a perspective view illustrating a holding unit;

FIG. 8 is a perspective view illustrating shelves;

FIG. 9 is a perspective view illustrating case opening units and a cutting blade conveying unit;

FIG. 10 is a perspective view illustrating the case opening units and the cutting blade conveying unit when the cutting blade is taken out from the case;

FIG. 11 is a perspective view illustrating the case opening units and the cutting blade conveying unit when the cutting blade is conveyed to a second conveying part;

FIG. 12 is a perspective view illustrating the case opening units and the cutting blade conveying unit when a transferring part of the second conveying part is erected;

FIG. 13 is a perspective view illustrating the case opening units and the cutting blade conveying unit when the cutting blade is transferred;

FIG. 14 is a perspective view illustrating the case opening units and the cutting blade conveying unit when handing-over of the cutting blades is executed;

FIG. 15 is a perspective view illustrating the case opening units and the cutting blade conveying unit when the cutting blade is carried out;

FIG. 16 is a perspective view illustrating collecting units;

FIG. 17 is a front view illustrating a first modification example of the cutting blade stock apparatus; and

FIG. 18 is a front view illustrating a second modification example of the cutting blade stock apparatus.

### DETAILED DESCRIPTION OF THE PREFERRED EMBODIMENT

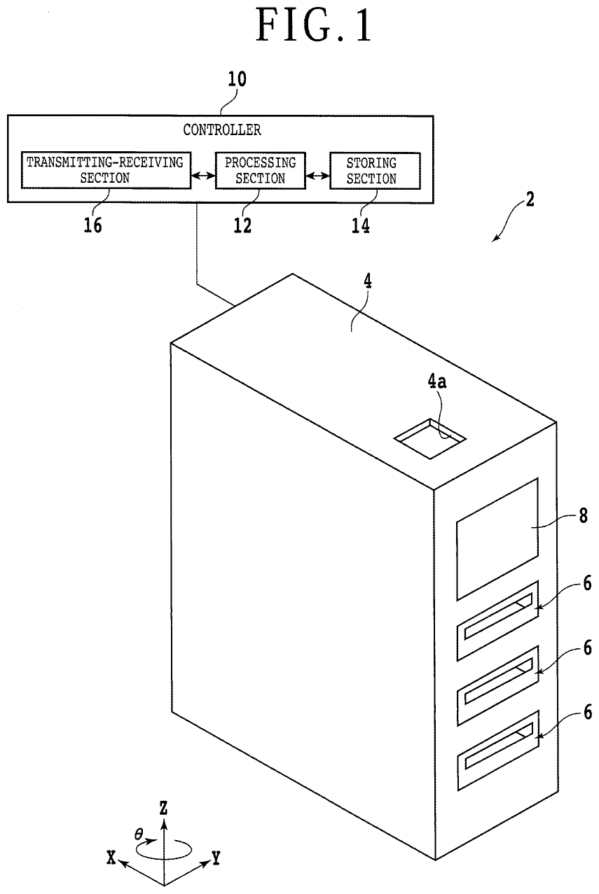

An embodiment according to one aspect of the present invention will be described below with reference to the accompanying drawings. First, a configuration example of a cutting blade stock apparatus according to the present embodiment will be described. FIG. 1 is a perspective view illustrating a cutting blade stock apparatus (cutting blade stocker) 2. The cutting blade stock apparatus 2 houses and stocks multiple cutting blades that are processing tools used for cutting of a workpiece. In FIG. 1, an X-axis direction (front-rear direction, first horizontal direction) and a Y-axis direction (left-right direction, second horizontal direction) are directions perpendicular to each other. Further, a Z-axis direction (height direction, vertical direction, upward-downward direction) is the direction perpendicular to the X-axis direction and the Y-axis direction. Moreover, a θ-direction is equivalent to a rotation direction that is parallel to the X-axis direction and the Y-axis direction and is around the Z-axis direction as the rotation axis.

The cutting blade stock apparatus 2 includes a rectangular parallelepiped-shaped cover (casing) 4 that houses the respective constituent elements that configure the cutting blade stock apparatus 2. A conveyance port 4a through which the cutting blade passes at the time of carrying-in and carrying-out of the cutting blade is made on the upper surface side of the cover 4. However, there is no limit on the position of the conveyance port 4a and the conveyance port 4a may be made in the front face, the back surface, or a side surface of the cover 4, for example.

On the front face side of the cover 4, multiple case placement stages (case housing shelves) 6 in which cases that can house the cutting blade are placed are disposed. The case placement stages 6 are drawer-type housing parts formed into a rectangular parallelepiped box shape, for example, and are housed in the cover 4 slidably along the X-axis direction. The case placement stages 6 are disposed at multiple stages at predetermined intervals along the height direction of the cover 4 (Z-axis direction). Although the case placement stages 6 at three stages are illustrated in FIG. 1, there is no limit on the number of stages of the case placement stage 6. The worker withdraws the case placement stage 6 and places and houses the case that houses the cutting blade in the case placement stage 6.

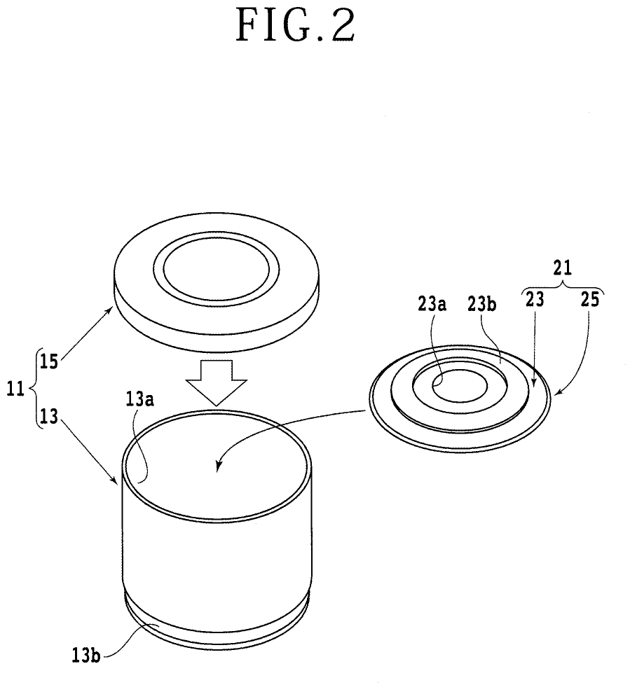

FIG. 2 is a perspective view illustrating a case (blade case) 11 that can house a cutting blade 21. The case 11 includes a columnar container 13 that houses the cutting blade 21 and a lid 15 that closes the container 13. A circular columnar housing part 13a that opens on the upper surface side of the container 13 is made inside the container 13. Further, a recess part 13b supported at the time of conveyance of the case 11 is made at a lower part of the container 13. The recess part 13b is annularly formed along the circumferential direction of the container 13 in such a manner as to enter the center side from the outer circumferential surface of the container 13. The lid 15 is formed into a circular disc shape corresponding to the diameter of the container 13 and is mounted on the upper surface side of the container 13. When the lid 15 is mounted on the container 13, the housing part 13a is covered and closed.

The cutting blade 21 with an annular shape is housed in the case 11. The cutting blade 21 is a processing tool used for cutting of a workpiece such as a semiconductor wafer or resin package substrate and is used when cutting processing is executed for the workpiece by cutting apparatus. Specifically, the cutting apparatus includes a chuck table (holding table) that holds the workpiece and a cutting unit that executes cutting processing for the workpiece. A spindle is incorporated in the cutting unit and the cutting blade 21 is mounted on a tip part of the spindle. The workpiece is cut and divided by holding the workpiece by the chuck table and causing the cutting blade 21 to cut into the workpiece while rotating the cutting blade 21.

The cutting blade 21 mounted in the cutting apparatus is replaced by another cutting blade 21 at a predetermined timing. For example, the kind of cutting blade 21 used for cutting of the workpiece is selected according to the kind of workpiece and a processing condition. Thus, replacement of the cutting blade 21 is executed every time the kind of workpiece or the processing condition is changed. Further, the cutting blade 21 gradually wears due to cutting of the workpiece. Therefore, when the amount of wear of the cutting blade 21 exceeds a certain amount, the cutting blade 21 that has been used is replaced by the cutting blade 21 as a new product.

For example, the cutting blade 21 is a cutting blade of a hub type (hub blade) including a hub base 23 with a circular disc shape and an annular cutting edge 25 formed along the outer circumferential edge of the hub base 23. The hub base 23 is an annular component composed of a metal such as an aluminum alloy and a circular through-hole 23a that penetrates the hub base 23 in the thickness direction is made at a central part of the hub base 23. Further, an annular projection part 23b that protrudes from the front surface of the hub base 23 is disposed on the front surface side of the hub base 23. The projection part 23b is formed concentrically with the hub base 23 in a region between the outer circumferential edge of the hub base 23 and the through-hole 23a. The cutting edge 25 is formed to protrude outward in the radial direction of the hub base 23 from the outer circumferential edge of the hub base 23. For example, the cutting edge 25 includes electroformed abrasive grains containing abrasive grains composed of diamond, cubic boron nitride (cBN), or the like and a bond such as a nickel plating layer that fixes the abrasive grains. However, the material and the grain diameter of the abrasive grains and the material of the bond are selected as appropriate according to specifications of the cutting blade 21. The cutting blade 21 may be a cutting blade of a washer type (washer blade). The washer blade includes only an annular cutting edge containing abrasive grains and a bond that fixes the abrasive grains. For example, diamond is used as the abrasive grains and a resin bond, metal bond, or vitrified bond is used as the bond.

The container 13 is formed in such a manner that the diameter of the housing part 13a is larger than the diameter of the cutting blade 21. Further, multiple (for example, 10) cutting blades 21 are housed in the housing part 13a of the container 13 in an overlapped manner. Moreover, the cutting blade 21 is prevented from accidentally going out of the container 13 by closing the container 13 in which multiple cutting blades 21 are housed by the lid 15.

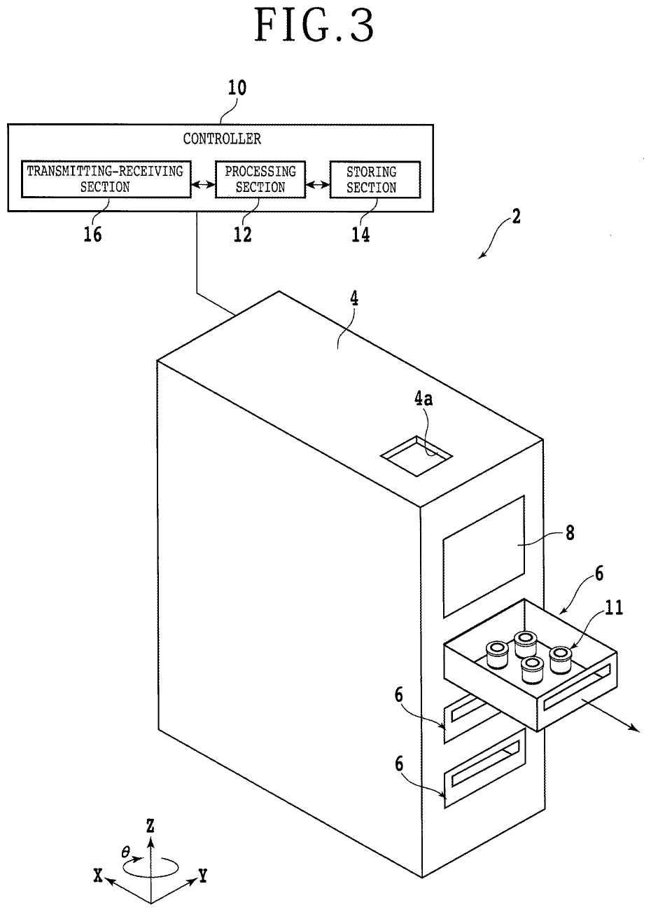

FIG. 3 is a perspective view illustrating the cutting blade stock apparatus 2 in the state in which the cases 11 are placed in the case placement stage 6. The case placement stage 6 is formed with a size that allows housing of multiple cases 11. After putting the cutting blades 21 in the case 11 (see FIG. 2), the worker withdraws the predetermined case placement stage 6 and houses the case 11 in the case placement stage 6. This restocks the cutting blade stock apparatus 2 with the cutting blades 21. The case placement stage 6 supports the multiple cases 11 by a flat support surface and does not include a partition that segments the inside of the case placement stage 6 into multiple regions in which the individual cases 11 are placed. Thus, the case 11 can be placed at an optional position in the case placement stage 6 and the worker does not need to position the case 11 to a specific place in the case placement stage 6. Due to this, placement work of the case 11 is simplified.

An input interface 8 to which various kinds of information are input is disposed on the front face side of the cover 4. For example, the input interface 8 includes a display of a touch panel system. In this case, an operation screen for inputting information to the cutting blade stock apparatus 2 is displayed on the input interface 8 and the operator can input information to the cutting blade stock apparatus 2 by touch operation of the input interface 8. The display of the touch panel system functions also as a display part (display unit, display device) that displays various kinds of information. That is, the display of the touch panel system is equivalent to a unit in which the input interface 8 and the display part are integrated. The display part displays information relating to the cutting blade stock apparatus 2 and information relating to the cutting blade 21 stocked in the cutting blade stock apparatus 2. However, the input interface 8 and the display part may be installed independently of each other. For example, it is also possible to use a display other than the display of the touch panel system as the display part and use input devices such as a mouse and a keyboard disposed independently of the display separately as the input interface 8.

Further, the cutting blade stock apparatus 2 includes a controller (control unit, control part, control device) 10 that controls the cutting blade stock apparatus 2. The controller 10 is connected to the respective constituent elements that configure the cutting blade stock apparatus 2. For example, the controller 10 includes a computer. Specifically, the controller 10 includes processors such as a central processing unit (CPU) and a graphics processing unit (GPU) and memories such as a read only memory (ROM) and a random access memory (RAM). The controller 10 controls operation of the cutting blade stock apparatus 2 by outputting a control signal to constituent elements of the cutting blade stock apparatus 2.

In FIG. 1 and FIG. 3, blocks indicating the functional configuration of the controller 10 are illustrated. Specifically, the controller 10 includes a processing section 12 that processes information input to the controller 10, a storing section 14 that stores information (data, program, and so forth) used for processing by the processing section 12, and a transmitting-receiving section 16 that executes transmission and reception of information to and from the external of the controller 10. The transmitting-receiving section 16 is connected to another device (processing apparatus, control device, or the like) in a wired or wireless manner and functions as an input interface to which information is input from the other device.

When the cutting blade 21 is newly mounted in the cutting apparatus or when the cutting blade 21 that is mounted in the cutting apparatus and has been used is replaced by the cutting blade 21 that has not been used (cutting blade 21 as a new product), the worker inputs information that specifies the predetermined cutting blade 21 stocked in the cutting blade stock apparatus 2 to the input interface 8 or the transmitting-receiving section 16. Then, the cutting blade stock apparatus 2 carries out the specified cutting blade 21 from the conveyance port 4a. This allows the worker to immediately obtain the desired cutting blade 21.

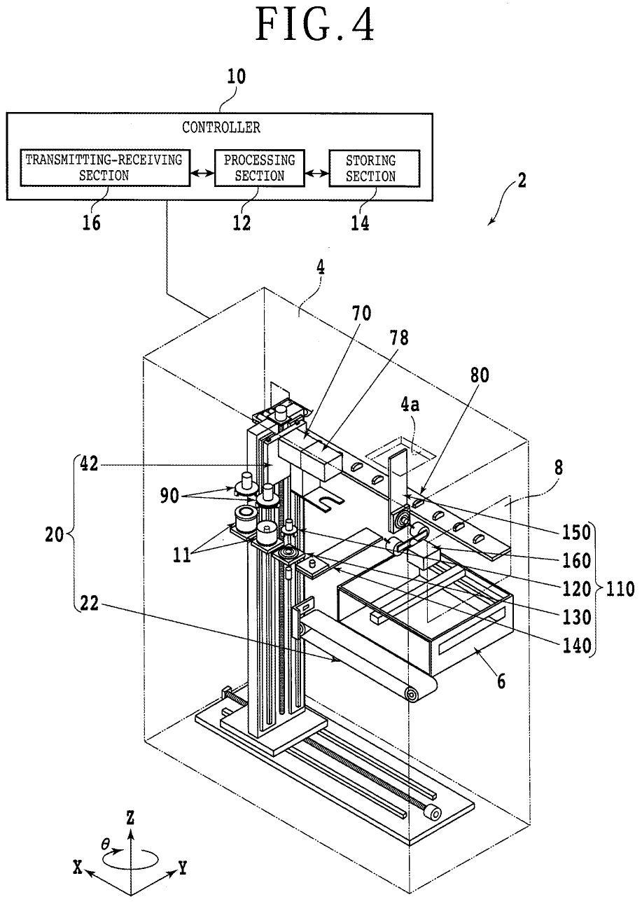

Next, details of the cutting blade stock apparatus 2 will be described. First, specific configuration and operation for stocking the cases 11 in the cutting blade stock apparatus 2 will be described. FIG. 4 is a perspective view illustrating constituent elements of the cutting blade stock apparatus 2. For convenience of explanation, the cover 4 and the input interface 8 are illustrated by dashed lines and only one stage of the case placement stage 6 is illustrated in FIG. 4.

The cutting blade stock apparatus 2 includes a case conveying unit 20 that conveys the case 11 placed in the case placement stage 6. The case conveying unit 20 includes a case transferring part 22 that transfers the case 11 placed (housed) in the case placement stage 6 to the outside of the case placement stage 6 and a case conveying part 42 that conveys the case 11 transferred by the case transferring part 22 to a shelf 80 to be described later.

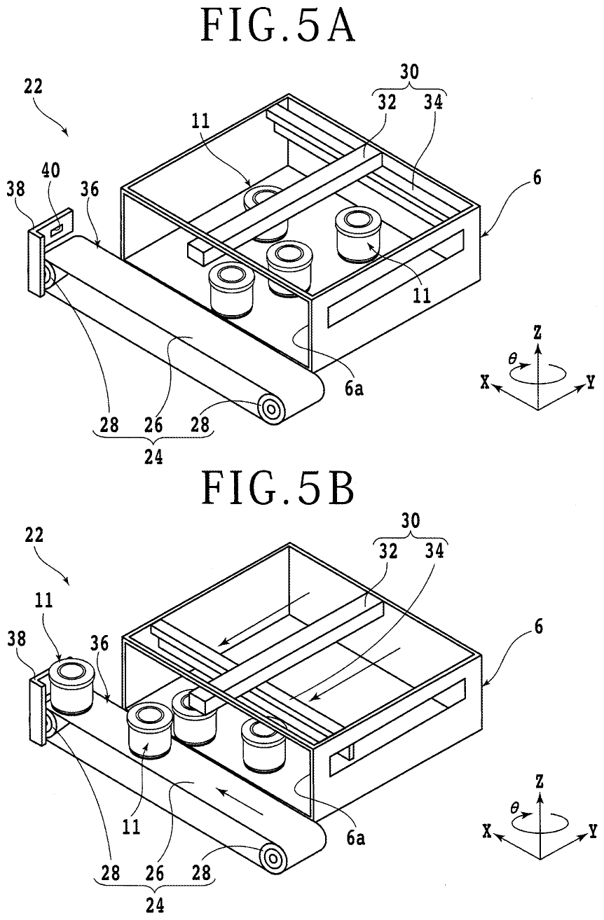

FIG. 5A is a perspective view illustrating the case transferring part 22. The case transferring part 22 includes a belt conveyor 24, a case moving part 30 that moves the cases 11 placed in the case placement stage 6 to the belt conveyor 24, and a temporary placement region 36 in which the case 11 conveyed by the belt conveyor 24 is temporarily placed. The belt conveyor 24 is installed on a lateral side of the case placement stage 6 and includes a strip-shaped belt 26 formed in a closed loop manner and a pair of pulleys 28 that support the belt 26. The pair of pulleys 28 are disposed separately from each other in the X-axis direction. Further, a rotational drive source (not illustrated) such as a motor that rotates the pulley is coupled to each of the pair of pulleys 28. The belt 26 is wound around the pair of pulleys 28 and is disposed along the X-axis direction. The case moving part 30 includes a columnar guide rail 32 disposed along the Y-axis direction and a moving component 34 mounted on the guide rail 32. For example, the moving component 34 is formed into a column shape and is disposed along the X-axis direction. Further, the moving component 34 is slidably mounted on the guide rail 32 with the interposition of a movement mechanism (not illustrated) that moves the moving component 34 along the Y-axis direction. As the movement mechanism, a movement mechanism of a ball screw system or an air cylinder can be used.

When the case placement stage 6 in which multiple cases 11 are placed has been set in the cover 4 (see FIG. 1), the guide rail 32 and the moving component 34 enter the inside of the case placement stage 6. At this time, the moving component 34 is disposed at an initial position to be along the inner wall of the case placement stage 6 located on the opposite side to the belt conveyor 24.

FIG. 5B is a perspective view illustrating the case transferring part 22 that transfers the cases 11. When the case placement stage 6 has been set, the belt conveyor 24 and the case moving part 30 operate. Specifically, the pair of pulleys 28 rotate and the upper layer of the belt 26 moves in the X-axis direction from the front side toward the rear side. Moreover, the moving component 34 moves toward the side of the belt conveyor 24 along the Y-axis direction. When the belt conveyor 24 and the case moving part 30 operate, the multiple cases 11 placed in the case placement stage 6 are pushed out by the moving component 34. This causes the multiple cases 11 to be disposed on the belt 26 through an opening 6a made in a side surface of the case placement stage 6. The length of the moving component 34 is adjusted as appropriate to allow all cases 11 placed in the case placement stage 6 to be pushed out to the belt conveyor 24. For example, the length of the moving component 34 is set equal to or larger than the depth (length in the X-axis direction) of the case placement stage 6. Then, after the cases 11 are pushed out from the case placement stage 6, the moving component 34 returns to the initial position. The multiple cases 11 disposed on the belt 26 are transferred to the rear side by the belt conveyor 24 and are temporarily placed in the temporary placement region 36. For example, a restraining component 38 that supports and restrains the case 11 is disposed at a rear end part of the belt conveyor 24. The case 11 carried by the belt conveyor 24 gets contact with the restraining component 38 and stops at the temporary placement region 36. Further, a sensor 40 (see FIG. 5A) that senses the case 11 is disposed on the restraining component 38. For example, an optical sensor or a switch (touch switch, press button, or the like) is used as the sensor 40. The belt conveyor 24 stops when the case 11 has gotten close to or contact with the sensor 40 and the sensor 40 has sensed the case 11.

While the moving component 34 is not disposed at the initial position (see FIG. 5A), the case placement stage 6 is locked in the state in which it is housed in the cover 4, and opening and closing (movement in the X-axis direction) of the case placement stage 6 are limited. This can prevent the occurrence of the situation in which the case placement stage 6 moves in the middle of movement of the cases 11 from the case placement stage 6 to the belt conveyor 24 and the transfer of the cases 11 is inhibited. Whether or not the moving component 34 is disposed at the initial position is sensed by a sensor (not illustrated) included in the case moving part 30, for example.

Moreover, the case transferring part 22 may have a function of placing, on the case placement stage 6 again, the case 11 placed on the belt conveyor 24 and the case 11 that sticks out from the opening 6a of the case placement stage 6. For example, the case transferring part 22 includes a case re-moving part (not illustrated) that returns the case 11 onto the case placement stage 6 on the lateral side of the belt conveyor 24 on the opposite side to the case placement stage 6. For example, the case re-moving part is configured similarly to the case moving part 30 and includes a columnar re-moving component that pushes back, onto the case placement stage 6, the case 11 placed on the belt conveyor 24 and the case 11 that sticks out from the opening 6a of the case placement stage 6. Further, the case 11 is pushed back onto the case placement stage 6 by the re-moving component immediately before the case placement stage 6 is opened or closed. This can prevent the case 11 from being left alone on the belt conveyor 24.

In this manner, the cases 11 placed (housed) in the case placement stage 6 are transferred to the temporary placement region 36. Thereafter, the cases 11 temporarily placed in the temporary placement region 36 are conveyed one by one by the case conveying part 42 (see FIG. 4).

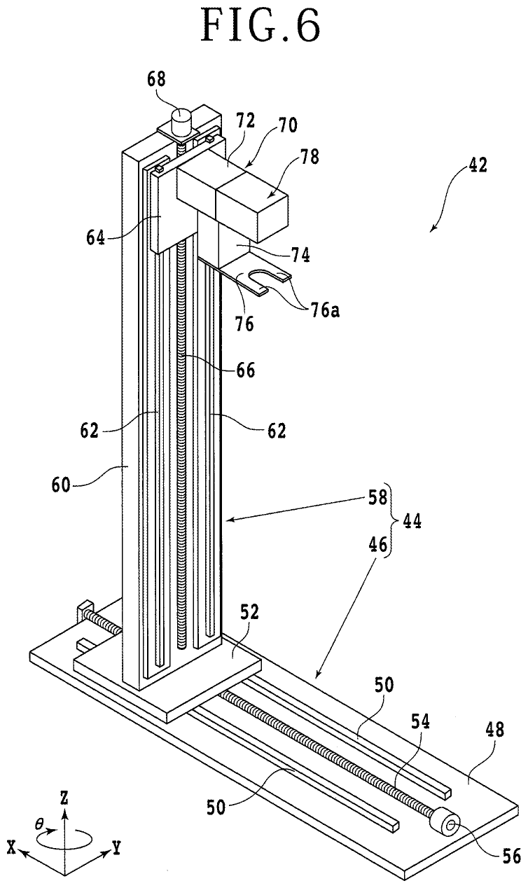

FIG. 6 is a perspective view illustrating the case conveying part 42. The case conveying part 42 includes a movement mechanism 44 and a holding unit 70 that holds the case 11. The movement mechanism 44 includes an X-axis movement mechanism 46 and a Z-axis movement mechanism 58 and moves the holding unit 70 along the X-axis direction and the Z-axis direction.

The X-axis movement mechanism 46 includes a support base 48 with a flat plate shape and a pair of X-axis guide rails 50 disposed along the X-axis direction on the upper surface of the support base 48. An X-axis moving plate 52 with a flat plate shape is mounted on the pair of X-axis guide rails 50 slidably along the X-axis guide rails 50. A nut part (not illustrated) is disposed on the back surface (lower surface) side of the X-axis moving plate 52. An X-axis ball screw 54 disposed along the X-axis direction between the pair of X-axis guide rails 50 is screwed to this nut part. Moreover, an X-axis pulse motor 56 that rotates the X-axis ball screw 54 is coupled to an end part of the X-axis ball screw 54. When the X-axis ball screw 54 is rotated by the X-axis pulse motor 56, the X-axis moving plate 52 moves in the X-axis direction along the X-axis guide rails 50.

The Z-axis movement mechanism 58 includes a rectangular parallelepiped-shaped support structure 60 disposed on the upper surface of the X-axis moving plate 52. The support structure 60 is disposed along the Z-axis direction and a pair of Z-axis guide rails 62 are disposed along the Z-axis direction on the front surface (front face) side of the support structure 60. Further, a Z-axis moving plate 64 with a flat plate shape is mounted on the pair of Z-axis guide rails 62 slidably along the Z-axis guide rails 62. A nut part (not illustrated) is disposed on the back surface (back face) side of the Z-axis moving plate 64. A Z-axis ball screw 66 disposed along the Z-axis direction between the pair of Z-axis guide rails 62 is screwed to this nut part. Moreover, a Z-axis pulse motor 68 that rotates the Z-axis ball screw 66 is coupled to an end part of the Z-axis ball screw 66. When the Z-axis ball screw 66 is rotated by the Z-axis pulse motor 68, the Z-axis moving plate 64 moves in the Z-axis direction along the Z-axis guide rails 62.

In the above, the case in which the X-axis movement mechanism 46 and the Z-axis movement mechanism 58 are movement mechanisms of a ball screw system has been described. However, there is no limit on the kind of X-axis movement mechanism 46 and Z-axis movement mechanism 58. For example, the X-axis movement mechanism 46 and the Z-axis movement mechanism 58 may each include an endless belt (timing belt) stretched between a drive pulley and a driven pulley. In this case, the X-axis moving plate 52 is fixed to the belt of the X-axis movement mechanism 46 and the position of the X-axis moving plate 52 in the X-axis direction is controlled through movement of the belt. Further, the Z-axis moving plate 64 is fixed to the belt of the Z-axis movement mechanism 58 and the position of the Z-axis moving plate 64 in the Z-axis direction is controlled through movement of the belt.

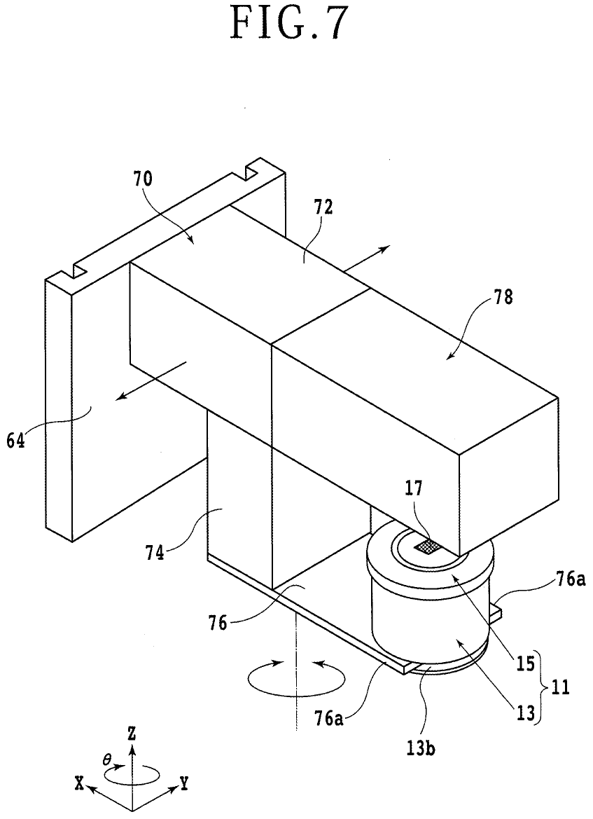

The holding unit 70 is coupled to the movement mechanism 44. The holding unit 70 moves along the X-axis direction and the Z-axis direction by the movement mechanism 44 in the state in which the holding unit 70 holds the case 11 (see FIG. 7). Specifically, when the X-axis moving plate 52 is moved by the X-axis movement mechanism 46, the holding unit 70 moves (advances and retreats) along the X-axis direction. Moreover, when the Z-axis moving plate 64 is moved by the Z-axis movement mechanism 58, the holding unit 70 moves (rises and lowers) along the Z-axis direction.

FIG. 7 is a perspective view illustrating the holding unit 70. The holding unit 70 includes a moving part (moving block) 72 mounted on the Z-axis moving plate 64. The moving part 72 is coupled to the Z-axis moving plate 64 with the interposition of a Y-axis movement mechanism (not illustrated). The Y-axis movement mechanism is a movement mechanism of a ball screw system, for example, and a nut part (not illustrated) disposed on the moving part 72 is screwed to a ball screw of the Y-axis movement mechanism. When the Y-axis movement mechanism is actuated, the moving part 72 moves along the Y-axis direction. A rotating part (rotating block) 74 is mounted on the lower surface side of a front end part of the moving part 72. The rotating part 74 is coupled to the moving part 72 with the interposition of a rotation mechanism (not illustrated). The rotation mechanism is a motor incorporated in the moving part 72, for example, and the rotating part 74 is fixed to an output shaft (rotating shaft) of the rotation mechanism. When the rotation mechanism is actuated, the rotating part 74 rotates in the θ-direction. A holding part (holding component) 76 that holds the case 11 is fixed to the lower surface side of the rotating part 74. For example, the holding part 76 is formed into a flat plate shape and is fixed to protrude forward from a lower end part of the rotating part 74. A front end part of the holding part 76 bifurcates to configure a pair of support parts 76a that support the case 11. When the pair of support parts 76a are inserted into the recess part 13b formed in the container 13 of the case 11, the case 11 is held by the pair of support parts 76a.

As described above, the holding part 76 is coupled to the movement mechanism 44 with the interposition of the rotating part 74 and the moving part 72. Thus, the holding part 76 can move along the X-axis direction, the Y-axis direction, and the Z-axis direction by the X-axis movement mechanism 46, the Y-axis movement mechanism, and the Z-axis movement mechanism 58 and can rotate in the θ-direction by the rotation mechanism. This makes it possible to position the holding part 76 to an optional position at an optional angle.

The case 11 temporarily placed in the temporary placement region 36 (see FIG. 5B) is conveyed by the case conveying part 42. Specifically, first, the holding part 76 is disposed on the rear side of the case placement stage 6 (see FIG. 5B). Further, the holding part 76 rotates and the pair of support parts 76a are disposed to face the case 11 temporarily placed in the temporary placement region 36 in the Y-axis direction. Next, the holding part 76 moves toward the side of the case 11 along the Y-axis direction and the pair of support parts 76a are inserted into the recess part 13b of the case 11. This causes the temporarily-placed case 11 to be held by the holding part 76. Thereafter, the holding part 76 that holds the case 11 moves along the X-axis direction, the Y-axis direction, and the Z-axis direction and rotates in the θ-direction to convey the case 11 to the shelf 80 (see FIG. 4) disposed inside the cover 4.

The case 11 is given identification information indicating the kind of case 11 (case identification information). Specifically, as illustrated in FIG. 7, a tag 17 is disposed on the case 11. The tag 17 includes the case identification information assigned according to the kind of cutting blade 21 (see FIG. 2) housed in the case 11. For example, a barcode or two-dimensional code including the case identification information is given to the case 11 as the tag 17. However, there is no limit on the kind of tag 17 as long as identification of the case 11 is possible. For example, the tag 17 may be an integrated circuit (IC) tag or radio frequency identifier (RFID) tag including the case identification information.

Moreover, a reading unit (case identification information reading unit) 78 that reads the case identification information given to the case 11 is mounted on the case conveying unit 20. For example, the reading unit 78 is mounted on a tip part of the moving part 72 included in the holding unit 70 as illustrated in FIG. 7. The reading unit 78 recognizes the tag 17 and reads the case identification information in the state in which the case 11 is held by the holding part 76. The kind of reading unit 78 is selected as appropriate according to the kind of tag 17. For example, when the tag 17 is a barcode or two-dimensional code, a barcode reader or two-dimensional code reader is used as the reading unit 78. Further, when the tag 17 is an IC tag or RFID tag, an IC reader or RFID reader is used as the reading unit 78. The reading unit 78 may be disposed on a constituent element other than the case conveying unit 20 as long as the case identification information can be read. However, when the reading unit 78 is mounted on the case conveying unit 20, the case identification information can be read in conveyance of the case 11 and therefore the work efficiency improves.

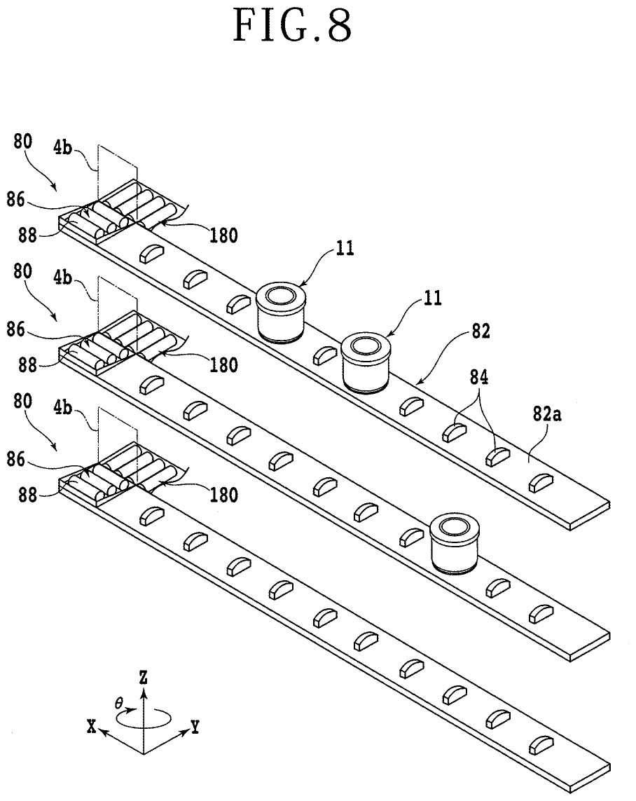

FIG. 8 is a perspective view illustrating the shelves 80. The shelves 80 are stock pedestals that support and stock the cases 11 conveyed by the case conveying unit 20 (see FIG. 4). The multiple shelves 80 are arranged in the Z-axis direction along an inner wall of the cover 4 (see FIG. 4). Although only one stage of the shelf 80 is illustrated as a representative example in FIG. 4, actually the shelves 80 at multiple stages are disposed as illustrated in FIG. 8.

The shelf 80 includes a support pedestal 82 that supports the cases 11. The support pedestal 82 is a plate-shaped component formed into a rectangular shape (strip shape) and is disposed with the length direction along the X-axis direction. The upper surface of the support pedestal 82 is a flat surface substantially parallel to the horizontal plane (XY-plane) and configures a support surface 82a that supports the cases 11. Further, multiple protrusions (projection parts) 84 are fixed to the side of the support surface 82a of the support pedestal 82. The multiple protrusions 84 are arranged at predetermined intervals along the length direction of the support pedestal 82 and the interval between the protrusions 84 is larger than the diameter of the case 11. On the lower surface side of the case 11, a groove (recess part) into which the protrusion 84 is inserted is formed (not illustrated). When the case 11 is disposed on the support pedestal 82 in such a manner as to overlap with the protrusion 84, the protrusion 84 is inserted into the groove of the case 11 and the case 11 is fixed.

Case carrying-out regions 86 in which the predetermined case 11 is placed are disposed at rear end parts of the support pedestals 82. In the case carrying-out regions 86, multiple rollers 88 are disposed to be juxtaposed. For example, an empty case 11 in which the cutting blade 21 is not housed or the case 11 filled with the cutting blades 21 that have been used is placed in the case carrying-out region 86. Moreover, when the case 11 is placed in the case carrying-out region 86, the multiple rollers 88 rotate due to the self-weight of the case 11 and the case 11 is carried out to the outside of the cover 4 through a conveyance port 4b of the cover 4. The carried-out case 11 is stocked in a collecting unit 180 to be described later and is collected. The specific case 11 specified by the worker may be placed in the case carrying-out region 86.

The case 11 temporarily placed in the temporary placement region 36 (see FIG. 5B) is conveyed to the shelf 80 by the case conveying part 42 (see FIG. 6). Moreover, while the case 11 is conveyed from the temporary placement region 36 to the shelf 80, the case identification information included in the tag 17 (see FIG. 7) given to the case 11 is read by the reading unit 78. Then, the case identification information is input from the reading unit 78 to the controller 10 (see FIG. 4).

The controller 10 stores the case identification information input from the reading unit 78 in the storing section 14 together with the storage site of the case 11. Specifically, the storage site of the case 11 from which the case identification information has been read is decided by the processing section 12 and the processing section 12 associates the case identification information with information indicating the storage site of the case 11 (case storage site information) and stores them in the storing section 14. For example, the case storage site information includes a sign indicating the specific shelf 80 (number of the shelf 80 or the like) and a sign indicating a specific position in the shelf 80 (number of the protrusion 84 or the like). Further, the processing section 12 outputs a control signal to the case conveying part 42 and controls the case conveying part 42 to cause the case 11 to be conveyed to a site specified by the case storage site information. Due to this, the case 11 is stored at a predetermined position on the predetermined shelf 80. In addition, the case identification information and the case storage site information are recorded in the controller 10.

In this manner, the case 11 with which the case placement stage 6 is restocked by the worker is stocked on the shelf 80. Moreover, when the worker specifies the predetermined cutting blade 21, the cutting blade stock apparatus 2 takes out the specified cutting blade 21 from the case 11 stocked on the shelf 80 and carries out it to the outside of the cutting blade stock apparatus 2.

Next, specific configuration and operation for carrying out the predetermined cutting blade 21 from the cutting blade stock apparatus 2 will be described. As illustrated in FIG. 4, the cutting blade stock apparatus 2 includes case opening units 90 that open the case 11 and a cutting blade conveying unit 110 that carries out the cutting blade 21 from the case 11 opened by the case opening unit 90.

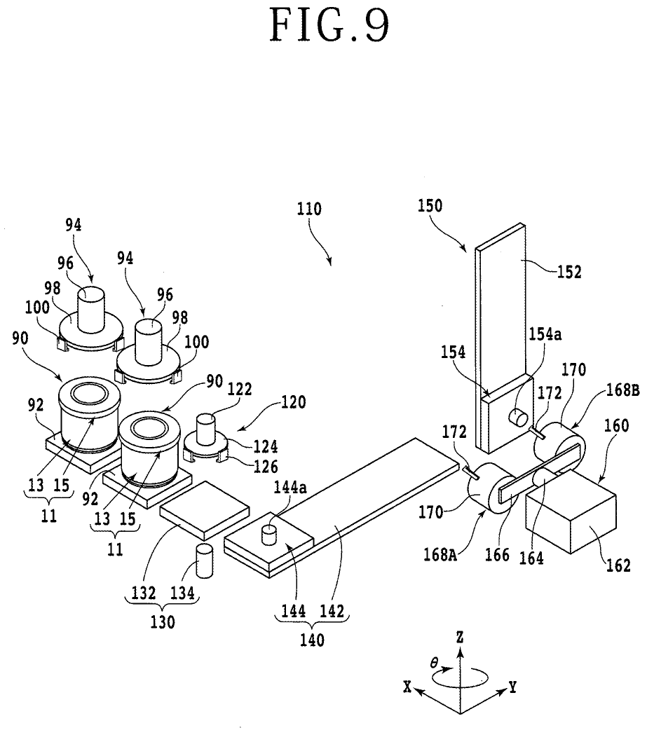

FIG. 9 is a perspective view illustrating the case opening units 90 and the cutting blade conveying unit 110. In FIG. 9, two sets of the case opening unit 90 and one set of the cutting blade conveying unit 110 are illustrated. However, the cutting blade stock apparatus 2 may include one set or three sets or more of the case opening unit 90 and may include two sets or more of the cutting blade conveying unit 110.

The case opening unit 90 includes a support pedestal 92 that supports the case 11 and an opening-closing unit 94 that opens and closes the lid 15 of the case 11. The support pedestal 92 is a component that can support the case 11 and is formed into a rectangular parallelepiped shape, for example. The upper surface of the support pedestal 92 is a flat surface substantially parallel to the horizontal plane (XY-plane) and configures a support surface that supports the case 11. The opening-closing unit 94 is disposed above the support pedestal 92. The opening-closing unit 94 includes a circular columnar support shaft 96 and a circular disc-shaped support component 98 fixed to a lower end part of the support shaft 96. Multiple clamps (grasping claws) 100 that grasp the lid 15 of the case 11 are disposed at an outer circumferential part of the support component 98. For example, three clamps 100 are disposed at substantially equal intervals (120° intervals) along the circumferential direction of the support component 98. A raising-lowering mechanism (not illustrated) that moves (raises and lowers) the opening-closing unit 94 along the Z-axis direction is coupled to the support shaft 96. As the raising-lowering mechanism, for example, an air cylinder or a movement mechanism of a ball screw system is used. Further, to each of the clamps 100, an actuator (not illustrated) that moves a tip part of the clamp 100 along the radial direction of the support component 98 is coupled.

The cutting blade conveying unit 110 is disposed on the front side of the opening-closing unit 94. The cutting blade conveying unit 110 includes a first conveying part 120 that executes taking-out and putting of the cutting blade 21 from and in the case 11 and conveyance of the cutting blade 21 and an identifying unit 130 that identifies the cutting blade 21.

The first conveying part 120 includes a circular columnar support shaft 122 and a circular disc-shaped support component 124 fixed to a lower end part of the support shaft 122. Multiple clamps (grasping claws) 126 that grasp the cutting blade 21 are disposed at an outer circumferential part of the support component 124. For example, three clamps 126 are disposed at substantially equal intervals (120° intervals) along the circumferential direction of the support component 124. A movement mechanism (not illustrated) that moves the first conveying part 120 along the X-axis direction and the Z-axis direction is coupled to the support shaft 122. As the movement mechanism, for example, a movement mechanism of a ball screw system is used. Further, to each of the clamps 126, an actuator (not illustrated) that moves a tip part of the clamp 126 along the radial direction of the support component 124 is coupled.

The identifying unit 130 includes a support pedestal 132 that supports the cutting blade 21 and a reading unit (blade identification information reading unit) 134 that reads blade identification information. The support pedestal 132 is a component that can support the cutting blade 21 and is formed into a rectangular parallelepiped shape, for example. The upper surface of the support pedestal 132 is a flat surface substantially parallel to the horizontal plane (XY-plane) and configures a support surface that supports the cutting blade 21. The reading unit 134 is disposed below the support pedestal 132 and reads the blade identification information given to the cutting blade 21. The blade identification information is identification information indicating the kind of cutting blade 21 and is given to the hub base 23 (see FIG. 2) of the cutting blade 21 as a tab, for example. Examples of the kind of tab are similar to those of the tag 17 (FIG. 7) given to the case 11. For example, the support pedestal 132 is composed of a transparent body such as quartz glass, borosilicate glass, sapphire, calcium fluoride, lithium fluoride, or magnesium fluoride. Moreover, the reading unit 134 reads the blade identification information given to the cutting blade 21 through the support pedestal 132.

However, a through-hole that penetrates the support pedestal 132 in the thickness direction may be made in the support pedestal 132. In this case, the reading unit 134 can read the blade identification information through the through-hole of the support pedestal 132 and therefore there is no limit on the material of the support pedestal 132. Further, an annular illuminator (not illustrated) may be disposed on the support pedestal 132. In this case, an outer circumferential part of the cutting blade 21 is supported by the annular illuminator. Turning on the illuminator to illuminate the cutting blade 21 makes reading of the blade identification information by the reading unit 134 easy.

A second conveying part 140, a third conveying part 150, and a fourth conveying part 160 that convey the cutting blade 21 are disposed on the front side of the identifying unit 130. The second conveying part 140 transfers the cutting blade 21 conveyed from the identifying unit 130 by the first conveying part 120. The third conveying part 150 carries out the cutting blade 21 to the external of the cutting blade stock apparatus 2. The fourth conveying part 160 executes handing-over of the cutting blade 21 between the second conveying part 140 and the third conveying part 150.

Specifically, the second conveying part 140 includes a support pedestal 142 and a transferring part 144 that transfers the cutting blade 21. The support pedestal 142 is a plate-shaped component formed into a rectangular shape (strip shape) and is disposed with the length direction along the Y-axis direction. The upper surface of the support pedestal 142 is a flat surface substantially parallel to the horizontal plane (XY-plane) and the transferring part 144 is mounted on the upper surface side of the support pedestal 142 slidably along the support pedestal 142. A movement mechanism (not illustrated) that moves the transferring part 144 along the length direction of the support pedestal 142 (Y-axis direction) is coupled to the transferring part 144. The transferring part 144 is formed into a rectangular shape, for example, and supports the cutting blade 21. A circular columnar protrusion (projection part) 144a that projects from the surface of the transferring part 144 is disposed at a central part of the transferring part 144. When the cutting blade 21 is disposed on the transferring part 144, the protrusion 144a is inserted into the through-hole 23a (see FIG. 2) of the cutting blade 21. This prevents a positional shift of the cutting blade 21.

The third conveying part 150 includes a support pedestal 152 and a transferring part 154 that transfers the cutting blade 21. The support pedestal 152 is a plate-shaped component formed into a rectangular shape (strip shape) and is disposed with the length direction along the Z-axis direction. A side surface of the support pedestal 152 is a flat surface substantially parallel to the YZ-plane and the transferring part 154 is mounted on the side surface side of the support pedestal 152 slidably along the support pedestal 152. A movement mechanism (not illustrated) that moves the transferring part 154 along the length direction of the support pedestal 152 (Z-axis direction) is coupled to the transferring part 154. The transferring part 154 is formed into a rectangular shape, for example, and supports the cutting blade 21. A circular columnar protrusion (projection part) 154a that projects from the surface of the transferring part 154 is disposed at a central part of the transferring part 154. When the cutting blade 21 is brought close to the transferring part 154, the protrusion 154a is inserted into the through-hole 23a (see FIG. 2) of the cutting blade 21. This causes the cutting blade 21 to be supported by the transferring part 154.

The fourth conveying part 160 includes a housing 162 with a rectangular parallelepiped shape. A circular columnar rotating shaft 164 disposed along the X-axis direction is housed in the housing 162. A tip part (one end part) of the rotating shaft 164 is exposed from the housing 162. Moreover, a rotational drive source (not illustrated) such as a motor housed in the housing 162 is coupled to a base end part (the other end part) of the rotating shaft 164. When the rotational drive source is actuated, the rotating shaft 164 rotates in both directions around a rotation axis substantially parallel to the X-axis direction. A support component 166 is fixed to the tip part of the rotating shaft 164. The support component 166 is formed into a rectangular shape, for example, and is disposed substantially in parallel to the YZ-plane. Further, a pair of blade holding units 168A and 168B that hold the cutting blade 21 are mounted on both end parts of the support component 166. The blade holding units 168A and 168B each include a circular columnar holding part 170 and multiple clamps (grasping claws) 172 mounted on an outer circumferential part of the holding part 170. For example, three clamps 172 are disposed at substantially equal intervals (120° intervals) along the circumferential direction of the holding part 170. However, there is no limit on the number of clamps 172. A movement mechanism (not illustrated) that moves the fourth conveying part 160 along the X-axis direction is coupled to the fourth conveying part 160. As the movement mechanism, for example, a movement mechanism of a ball screw system is used. Moreover, to each of the clamps 172, an actuator (not illustrated) that moves a tip part of the clamp 172 along the radial direction of the holding part 170 is coupled.

When the cutting blade 21 is carried out from the cutting blade stock apparatus 2, first, a worker inputs information that specifies the cutting blade 21 to be carried out by the cutting blade conveying unit 110 to the input interface 8 or the transmitting-receiving section 16 of the controller 10 illustrated in FIG. 4. Thereupon, the processing section 12 of the controller 10 accesses the storing section 14 and identifies the position of the shelf 80 on which the case 11 that houses the specified cutting blade 21 is stored. Then, the processing section 12 outputs a control signal to the case conveying part 42 to cause the case 11 stored at the identified position to be conveyed to the case opening unit 90. Then, the case 11 is opened by the case opening unit 90 and the cutting blade 21 is taken out from the case 11 and is carried out from the cutting blade stock apparatus 2 through the conveyance port 4a by the cutting blade conveying unit 110. This allows the worker to rapidly obtain the desired cutting blade 21 without executing work of searching for the specific cutting blade 21 from a large number of cutting blades 21.

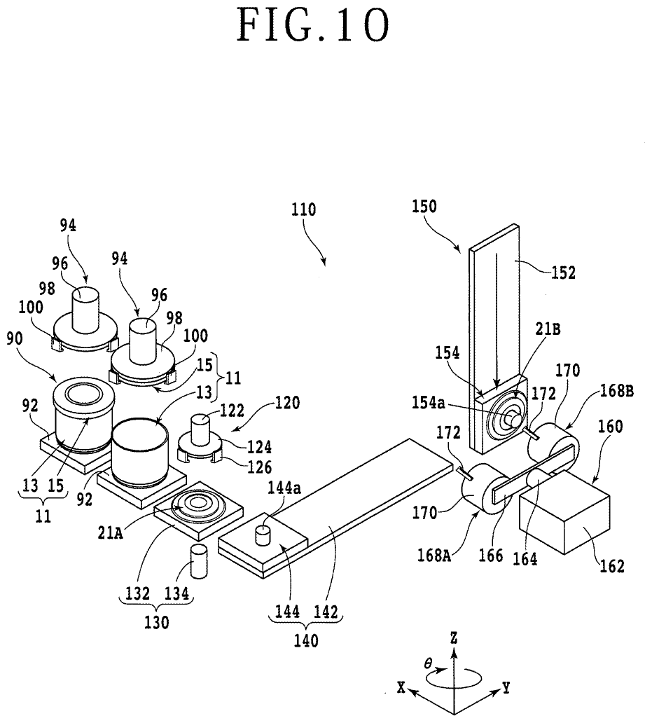

Next, operation of the case opening unit 90 and the cutting blade conveying unit 110 at the time of carrying-out of the cutting blade 21 will be described with reference to FIG. 10 to FIG. 15. In the following, as one example, description will be made about the case in which the cutting blade 21 that has not been used (new product) (cutting blade 21A) is carried out from the cutting blade stock apparatus 2 and the cutting blade 21 that has been used (cutting blade 21B) is carried in to the cutting blade stock apparatus 2.

FIG. 10 is a perspective view illustrating the case opening units 90 and the cutting blade conveying unit 110 when the cutting blade 21A is taken out from the case 11. As described above, when the predetermined cutting blade 21A is specified by a worker, the case 11 that houses the cutting blade 21A is conveyed onto the support pedestal 92 of the case opening unit 90. Then, a lower part of the case 11 is fixed to the support pedestal 92 by a fixing mechanism (not illustrated) such as a clamp disposed on the support pedestal 92.

Subsequently, the opening-closing unit 94 lowers and the multiple clamps 100 grasp an outer circumferential part of the lid 15 of the case 11. Thereafter, the opening-closing unit 94 rises in the state in which it holds the lid 15. As a result, the lid 15 is separated from the container 13 and the case 11 is opened. This makes it possible to take out the cutting blade 21A housed in the case 11.

Next, the first conveying part 120 is positioned directly above the opened case 11. Then, the first conveying part 120 lowers and enters the inside of the container 13 and the lower surface side of the support component 124 gets contact with the cutting blade 21A housed in the container 13. Further, the multiple clamps 126 move toward the center side of the support component 124 and grasp the outer circumferential surface of the projection part 23b (see FIG. 2) of the cutting blade 21A. Thereafter, the first conveying part 120 rises and the cutting blade 21A is taken out from the container 13.

Subsequently, the first conveying part 120 that holds the cutting blade 21A is disposed directly above the support pedestal 132 of the identifying unit 130. Then, the first conveying part 120 lowers and the cutting blade 21A is placed on the support pedestal 132. In this state, the multiple clamps 126 move outward in the radial direction of the support component 124 and the grasping of the cutting blade 21A by the multiple clamps 126 is released. This causes the cutting blade 21A to be supported by the support pedestal 132.

Next, the blade identification information given to the cutting blade 21A is read by the reading unit 134. For example, a tag including the blade identification information is given to the cutting blade 21A. Moreover, the reading unit 134 reads the blade identification information from the tag and outputs it to the controller 10 (see FIG. 4). The controller 10 determines whether or not the cutting blade 21A is the predetermined kind of cutting blade specified by the worker by comparing information on the cutting blade input to the input interface 8 or the transmitting-receiving section 16 of the controller 10 by the worker and the blade identification information read by the reading unit 134. Through this, a final check about whether or not the kind of cutting blade 21A is correct is executed before the carrying-out of the cutting blade 21A. At this time, the read blade identification information may be displayed on the input interface 8 (display).

Further, in the case of executing carrying-in of the cutting blade 21B concurrently with the carrying-out of the cutting blade 21A, the cutting blade 21B is set on the transferring part 154 of the third conveying part 150. Then, the transferring part 154 passes through the conveyance port 4a (see FIG. 4) of the cover 4 and lowers along the support pedestal 152 to be disposed at a lower end part of the support pedestal 152. Through this, the cutting blade 21B is carried in to the cutting blade stock apparatus 2 through the conveyance port 4a. Then, the cutting blade 21B is positioned to face the blade holding unit 168B.

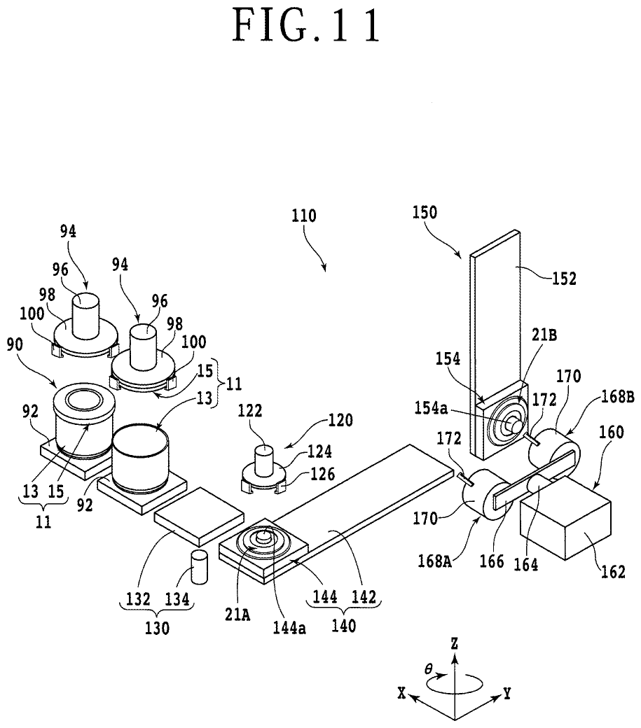

FIG. 11 is a perspective view illustrating the case opening units 90 and the cutting blade conveying unit 110 when the cutting blade 21A is conveyed to the second conveying part 140. After the reading of the blade identification information and the determination about whether the cutting blade 21A is correct or incorrect are executed, the cutting blade 21A is conveyed from the support pedestal 132 onto the transferring part 144 of the second conveying part 140 by the first conveying part 120. At this time, the protrusion 144a of the transferring part 144 is inserted into the through-hole 23a (see FIG. 2) of the cutting blade 21A.

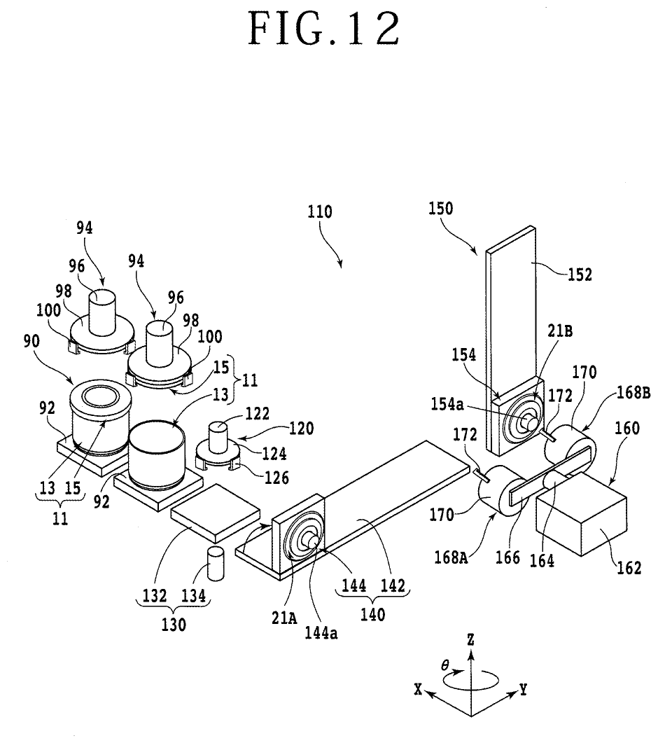

FIG. 12 is a perspective view illustrating the case opening units 90 and the cutting blade conveying unit 110 when the transferring part 144 of the second conveying part 140 is erected. A rotational drive source (not illustrated) such as a motor that rotates the transferring part 144 around a rotation axis substantially parallel to the Y-axis direction is coupled to the transferring part 144. When the rotational drive source is actuated, the transferring part 144 is switched from the lying state (support state, see FIG. 11) to the erected state (transfer state, see FIG. 12) and the cutting blade 21A is disposed along the YZ-plane.

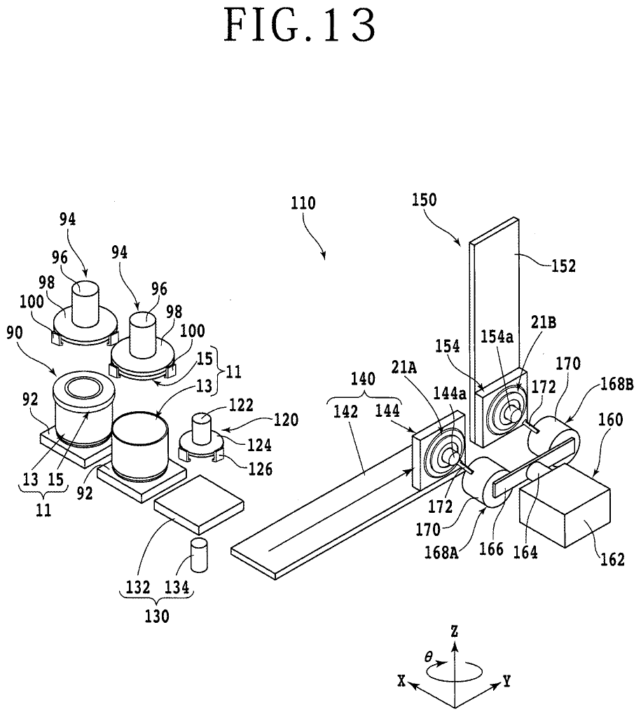

FIG. 13 is a perspective view illustrating the case opening units 90 and the cutting blade conveying unit 110 when the cutting blade 21A is transferred. When the transferring part 144 that supports the cutting blade 21A has been switched from the support state to the transfer state, the transferring part 144 slides along the support pedestal 142 and the cutting blade 21A is transferred from one end side (side of the identifying unit 130) of the support pedestal 142 to the other end side (side of the third conveying part 150 and the fourth conveying part 160). As a result, the cutting blade 21A is positioned to face the blade holding unit 168A.

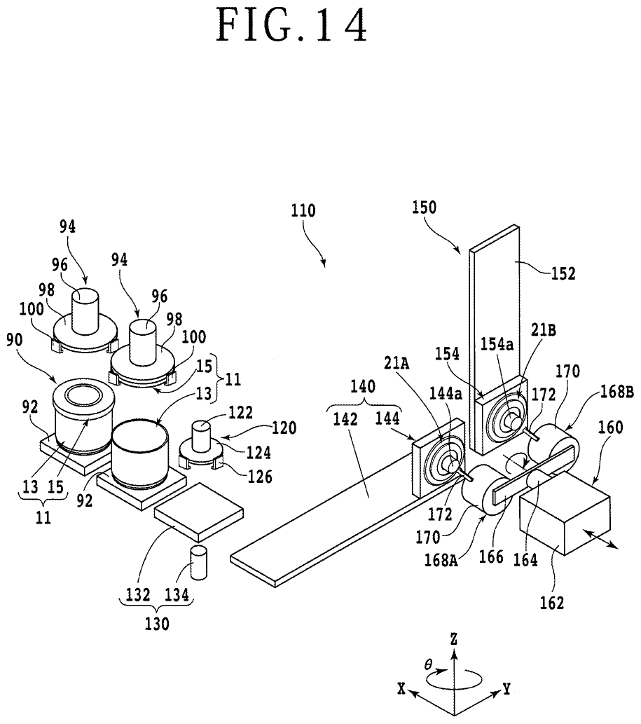

FIG. 14 is a perspective view illustrating the case opening units 90 and the cutting blade conveying unit 110 when handing-over of the cutting blades 21A and 21B is executed. When the cutting blades 21A and 21B have been positioned in front of the blade holding units 168A and 168B, respectively, the fourth conveying part 160 moves toward the side of the transferring parts 144 and 154 along the X-axis direction. This causes tip parts of the blade holding units 168A and 168B to get contact with the cutting blades 21A and 21B, respectively.

Next, the multiple clamps 172 included in the blade holding units 168A and 168B move toward the center side of the holding part 170. Due to this, the outer circumferential surface of the projection part 23b (see FIG. 2) of the cutting blade 21A is grasped by the clamps 172 of the blade holding unit 168A. Moreover, the outer circumferential surface of the projection part 23b (see FIG. 2) of the cutting blade 21B is grasped by the clamps 172 of the blade holding unit 168B.

Subsequently, the fourth conveying part 160 moves along the X-axis direction to separate from the transferring parts 144 and 154. This removes the cutting blades 21A and 21B from the transferring parts 144 and 154. Thereafter, the rotating shaft 164 rotates by 180° and the positions of the cutting blades 21A and 21B are interchanged. Due to this, the cutting blade 21A that has not been used faces the transferring part 154 of the third conveying part 150 and the cutting blade 21B that has been used faces the transferring part 144 of the second conveying part 140.

Next, the fourth conveying part 160 moves toward the side of the transferring parts 144 and 154 along the X-axis direction. Due to this, the protrusion 154a of the transferring part 154 is inserted into the through-hole 23a (see FIG. 2) of the cutting blade 21A and the protrusion 144a of the transferring part 144 is inserted into the through-hole 23a (see FIG. 2) of the cutting blade 21B. Further, the multiple clamps 172 included in the blade holding units 168A and 168B move outward in the radial direction of the holding part 170. This releases the grasping of the cutting blades 21A and 21B by the multiple clamps 172. As a result, the cutting blade 21A that has not been used is held by the transferring part 154 of the third conveying part 150 and the cutting blade 21B that has been used is held by the transferring part 144 of the second conveying part 140.

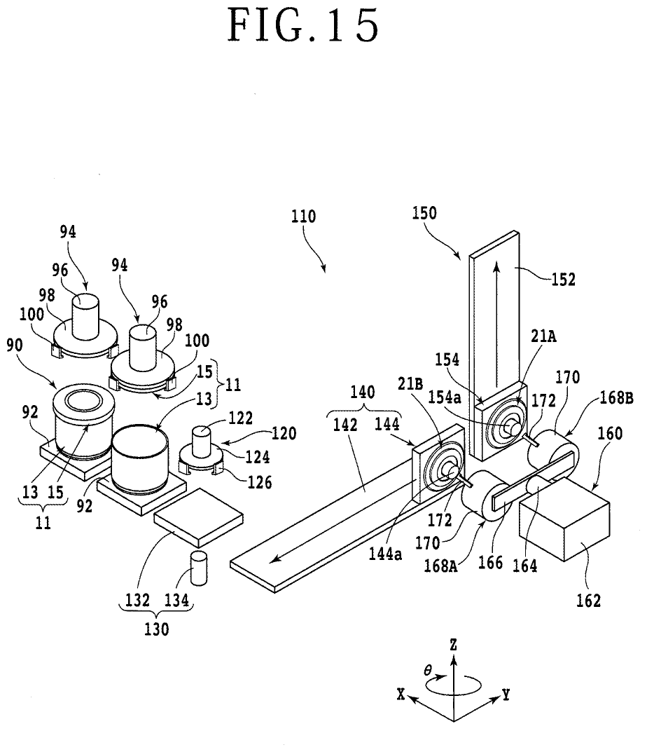

FIG. 15 is a perspective view illustrating the case opening units 90 and the cutting blade conveying unit 110 when the cutting blade 21A is carried out. When the cutting blade 21A that has not been used has been supported by the transferring part 154, the transferring part 154 rises along the support pedestal 152 and the cutting blade 21A is carried out to the outside of the cover 4 through the conveyance port 4a (see FIG. 4). This allows the worker to obtain the cutting blade 21A specified by oneself.

Moreover, when the cutting blade 21B that has been used has been supported by the transferring part 144, the transferring part 144 slides along the support pedestal 142 and moves toward the side of the identifying unit 130 and is switched from the erected state (transfer state) to the lying state (support state). Subsequently, the cutting blade 21B is held by the first conveying part 120 and is conveyed to the identifying unit 130. Then, the blade identification information given to the cutting blade 21B is read by the reading unit 134 and is output to the controller 10. This causes the kind of the carried-in cutting blade 21B to be recognized by the controller 10.

Next, the controller 10 outputs a control signal to the case conveying part 42 (see FIG. 4 and so forth) and conveys the case 11 in which the cutting blade 21B should be housed from the shelf 80 to the support pedestal 92 of the case opening unit 90. Further, the lid 15 is removed from the container 13 by the opening-closing unit 94 and the case 11 is opened. The cutting blade 21B is held by the first conveying part 120 and is housed in the case 11 in the opened state. Moreover, when the cutting blade 21B has been housed in the case 11, the lid 15 is closed by the case opening unit 90. Then, the case 11 that houses the cutting blade 21B is conveyed to a predetermined position on the predetermined shelf 80 by the case conveying part 42 (see FIG. 4 and so forth).

In this manner, the carrying-out of the cutting blade 21A from the cutting blade stock apparatus 2 and the carrying-in of the cutting blade 21B to the cutting blade stock apparatus 2 are executed. When carrying-in and carrying-out of the cutting blade 21 are repeated, part of the cases 11 becomes the empty state in which the cutting blade 21 is not housed or is filled with the cutting blades 21 that have been used in some cases. Such a case 11 may be carried out to the outside of the cutting blade stock apparatus 2 and be collected by a worker.

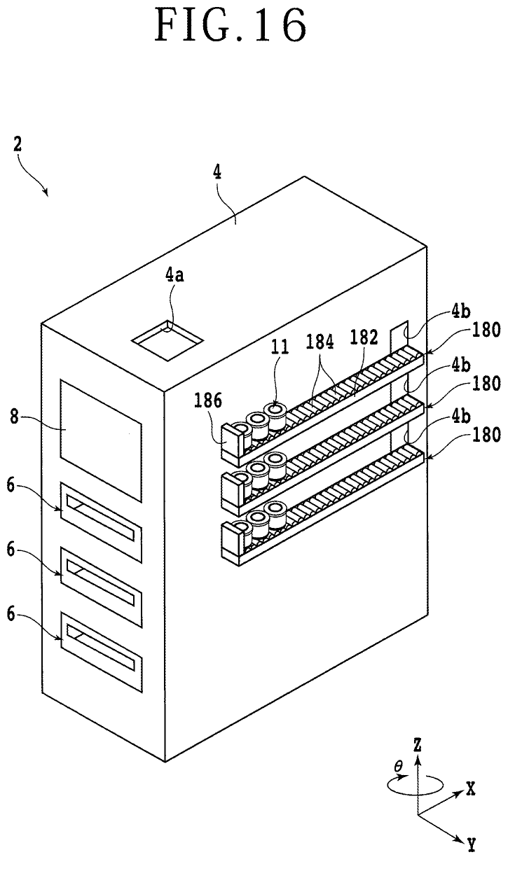

FIG. 16 is a perspective view illustrating the collecting units 180 disposed on the cutting blade stock apparatus 2. The collecting units 180 are mounted on an outer wall of the cover 4 and collect the case 11 (the empty case 11, the case 11 filled with the cutting blades 21 that have been used, or the like) discharged from the conveyance port 4b of the cover 4. For example, the same number of collecting units 180 as the shelves 80 (see FIG. 8) are disposed and are coupled to the shelves 80 through the conveyance ports 4b. However, there is no limit on the number of stages of the collecting units 180.

The collecting units 180 each include a columnar support pedestal 182 and multiple circular columnar rollers 184 supported by the support pedestal 182. The rollers 184 are disposed with the length direction along the Y-axis direction, and are arranged at substantially equal intervals along the length direction of the support pedestal 182. Further, restraining components 186 that support and restrain the case 11 are disposed at front end parts of the support pedestals 182. The support pedestals 182 are disposed along the XZ-plane and are slightly inclined with respect to the X-axis direction in such a manner that the front end side (side of the restraining component 186) is positioned on the lower side relative to the rear end side (conveyance port 4b side).

When the empty case 11 that does not house the cutting blade 21 or the case 11 filled with the cutting blades 21 that have been used exists in the cutting blade stock apparatus 2, such a case 11 is placed in the case carrying-out region 86 (see FIG. 8) of the shelf 80 by the case conveying part 42 (see FIG. 4). Moreover, the specific case 11 specified by a worker is placed in the case carrying-out region 86 in some cases. When the case 11 has been placed in the case carrying-out region 86, the rollers 88 rotate and the case 11 is transferred to the collecting unit 180 through the conveyance port 4b. Then, as illustrated in FIG. 16, the case 11 is transferred to the front end side of the support pedestal 182 by rotation of the rollers 184 and is restrained by the restraining component 186. Through this, the cases 11 are accumulated in the collecting unit 180 and the worker can collectively collect the cases 11 at a predetermined timing.

A conveyance path to convey the cutting blade 21 may be disposed over the cover 4 of the cutting blade stock apparatus 2. The conveyance path is installed to span to the cutting blade stock apparatus 2 and cutting apparatus that cuts a workpiece by the cutting blade 21 stocked in the cutting blade stock apparatus 2. Further, the cutting blade 21 is conveyed on the conveyance path by an unattended conveying vehicle that can be remotely operated.

Specifically, when the cutting blade 21 is mounted in the cutting apparatus, the cutting blade 21A (see FIG. that has been specified by a worker and been carried out from the cutting blade stock apparatus 2 is mounted on the conveying vehicle. Then, the conveying vehicle travels on the conveyance path and moves to above the cutting apparatus and passes the cutting blade 21 to the cutting apparatus. Through this, the conveyance of the cutting blade 21A from the cutting blade stock apparatus 2 to the cutting apparatus is automatically executed. On the other hand, when the cutting blade 21 mounted in the cutting apparatus is collected, the cutting blade 21 removed from the cutting apparatus is mounted on the conveying vehicle. Then, the conveying vehicle travels on the conveyance path and moves to above the cutting blade stock apparatus 2 and passes the cutting blade 21B (see FIG. 10) to the cutting blade stock apparatus 2 through the conveyance port 4a of the cover 4. Through this, the conveyance of the cutting blade 21B to the cutting blade stock apparatus 2 is automatically executed.

As above, when information that specifies the cutting blade 21 is input, the cutting blade stock apparatus 2 according to the present embodiment carries out the specified cutting blade 21 from the case 11 stocked on the shelf 80. Thus, the worker does not need to search for and pick up the specific cutting blade 21 from a large number of cutting blades 21 by oneself. Due to this, management of the cutting blades 21 is simplified and a mistake in taking the cutting blade 21 is prevented, so that the occurrence of processing failure and breakage of the cutting blade due to processing of a workpiece by the incorrect cutting blade 21 can be avoided.

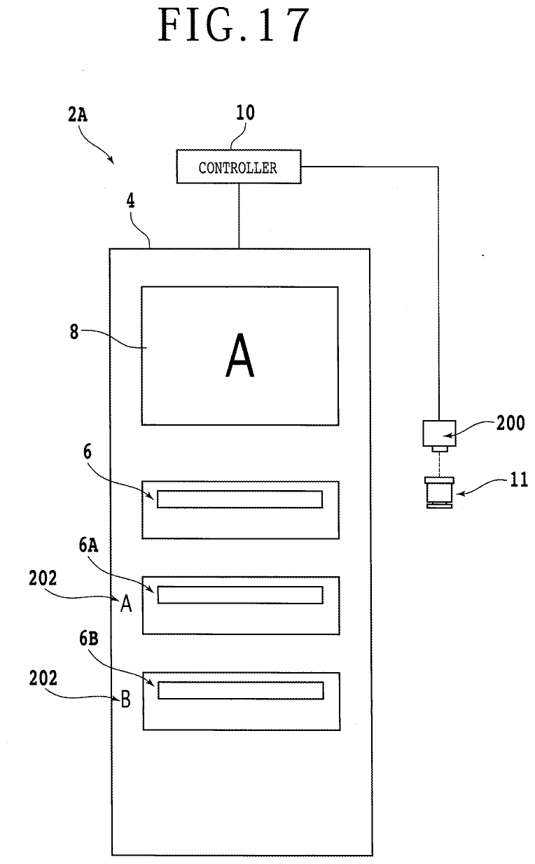

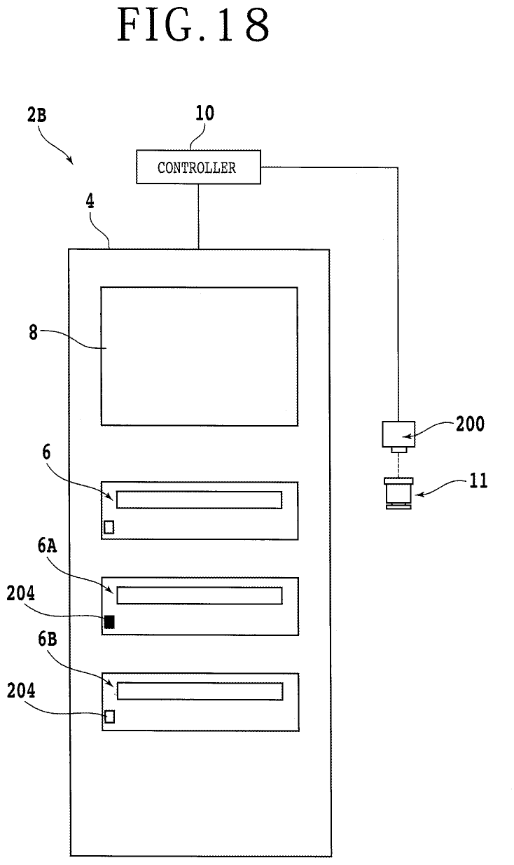

Part of the multiple case placement stages 6 included in the cutting blade stock apparatus 2 may be dedicated case placement stages 6 in which only a predetermined kind of case 11 (predetermined kind of cutting blade 21) is placed. Modification examples of the cutting blade stock apparatus 2 including the dedicated case placement stages 6 are illustrated in FIG. 17 and FIG. 18.

FIG. 17 is a front view illustrating a cutting blade stock apparatus 2A equivalent to a first modification example of the cutting blade stock apparatus 2. The cutting blade stock apparatus 2A includes a reading unit (case identification information reading unit) 200 that reads the case identification information given to the case 11. The reading unit 200 is installed outside the cover 4 and reads the case identification information of the case 11 before placement (housing) in the case placement stage 6. The kind, functions, and so forth of the reading unit 200 are similar to those of the reading unit 78 (FIG. 7).

Further, the cutting blade stock apparatus 2A includes dedicated case placement stages (dedicated case housing shelves) 6A and 6B. The dedicated case placement stages 6A and 6B are each equivalent to the dedicated case placement stage 6 in which only a predetermined kind of case 11 is placed. For example, the dedicated case placement stage 6A houses only the case 11 classified into kind A and the dedicated case placement stage 6B houses only the case 11 classified into kind B. Stage indication parts 202 indicating the kind of case placement stage are disposed on the dedicated case placement stages 6A and 6B or the periphery thereof. For example, characters, symbols, figures, or the like indicating the dedicated case placement stages 6A and 6B are given to the dedicated case placement stages 6A and 6B or the periphery thereof as the stage indication parts 202. FIG. 17 illustrates an example in which alphabets “A” and “B” that represent the dedicated case placement stages 6A and 6B, respectively, are given to the left side of the dedicated case placement stages 6A and 6B.

When the case 11 is stocked in the cutting blade stock apparatus 2A, first, a worker causes the reading unit 200 to read the case identification information included in the tag 17 (see FIG. 7) given to the case 11. Then, the reading unit 200 outputs the case identification information to the controller 10.

In the controller 10, the kinds of cases 11 that should be stocked in the dedicated case placement stages 6A and 6B are stored in advance. Then, the controller 10 determines whether or not the case 11 should be stocked in the dedicated case placement stage 6A or 6B on the basis of the case identification information input from the reading unit 200, and causes a display part to display the determination result. For example, when the case 11 should be housed in the dedicated case placement stage 6A, information indicating the dedicated case placement stage 6A (for example, alphabet “A”) is displayed on a display of a touch panel system that functions as the input interface 8 and the display part. In this case, the worker opens the dedicated case placement stage 6A and places the case 11 in the dedicated case placement stage 6A. Thereby, the case 11 is stocked in the dedicated case placement stage 6A.

On the other hand, when the cutting blade 21 stored in the cutting blade stock apparatus 2A is used, the worker inputs the kind of the desired cutting blade 21 to the input interface 8. Then, the controller 10 determines whether or not the case 11 that houses the input kind of cutting blade 21 is stocked in the dedicated case placement stage 6A or 6B, and causes the display part to display the determination result. For example, when the case 11 that houses the cutting blade 21 specified by the worker is stocked in the dedicated case placement stage 6A, information indicating the dedicated case placement stage 6A (for example, alphabet “A”) is displayed on the display of the touch panel system. In this case, the worker opens the dedicated case placement stage 6A and takes out the case 11. This allows the worker to rapidly obtain the desired cutting blade 21 from the cutting blade stock apparatus 2A.

FIG. 18 is a front view illustrating a cutting blade stock apparatus 2B equivalent to a second modification example of the cutting blade stock apparatus 2. The cutting blade stock apparatus 2B includes the reading unit 200 and the dedicated case placement stages 6A and 6B similarly to the cutting blade stock apparatus 2A. Display parts 204 indicating that the dedicated case placement stage 6A or 6B is specified (selected) are mounted on the dedicated case placement stages 6A and 6B or the periphery thereof. For example, indicator lights such as light emitting diode (LED) lamps are used as the display parts 204. FIG. 18 illustrates an example in which the display part 204 is mounted on each of the front faces of the dedicated case placement stages 6A and 6B.

When the case 11 is stocked in the cutting blade stock apparatus 2B, first, a worker causes the reading unit 200 to read the case identification information included in the tag 17 (see FIG. 7) given to the case 11. Then, the reading unit 200 outputs the case identification information to the controller 10.

In the controller 10, the kinds of cases 11 that should be stocked in the dedicated case placement stages 6A and 6B are stored in advance. Then, the controller 10 determines whether or not the case 11 should be stocked in the dedicated case placement stage 6A or 6B on the basis of the case identification information input from the reading unit 200, and turns on the display part 204 according to the determination result. For example, when the case 11 should be housed in the dedicated case placement stage 6A, the display part 204 disposed on the dedicated case placement stage 6A or the periphery thereof is turned on. In this case, the worker opens the dedicated case placement stage 6A and places the case 11 in the dedicated case placement stage 6A. Thereby, the case 11 is stocked in the dedicated case placement stage 6A.

On the other hand, when the cutting blade 21 is taken out from the cutting blade stock apparatus 2B, the worker inputs the kind of the desired cutting blade 21 to the input interface 8. Then, the controller 10 determines whether or not the case 11 that houses the input kind of cutting blade 21 is stocked in the dedicated case placement stage 6A or 6B, and turns on the display part 204 according to the determination result. For example, when the case 11 that houses the cutting blade 21 specified by the worker is stocked in the dedicated case placement stage 6A, the display part 204 disposed on the dedicated case placement stage 6A or the periphery thereof is turned on. In this case, the worker opens the dedicated case placement stage 6A and takes out the case 11. This allows the worker to rapidly obtain the desired cutting blade 21 from the cutting blade stock apparatus 2B.

Configurations and functions of the pieces of cutting blade stock apparatus 2A and 2B regarding which description is omitted in the above are similar to those of the cutting blade stock apparatus 2. For example, when the case 11 should not be stocked in the dedicated case placement stages 6A and 6B, a worker stocks the case 11 in the case placement stage 6. Further, when the case 11 that houses the cutting blade 21 specified by a worker is not stocked in the dedicated case placement stages 6A and 6B, the cutting blade stock apparatus 2A or 2B carries out the cutting blade 21 by operation similar to that of the cutting blade stock apparatus 2.

Besides, structures, methods, and so forth according to the above-described embodiment can be carried out with appropriate changes without departing from the range of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting blade stock apparatus that stocks a plurality of cutting blades used for cutting of a workpiece, the cutting blade stock apparatus comprising:
a case placement stage at which a case capable of housing the cutting blade is placed;
a case conveying unit that conveys the case placed at the case placement stage;
a shelf that supports and stocks the case conveyed by the case conveying unit;
a case identification information reading unit that reads case identification information given to the case;
a case opening unit that opens the case;
a cutting blade conveying unit that carries out the cutting blade from the case opened by the case opening unit; and
an input interface to which information that specifies the cutting blade to be carried out by the cutting blade conveying unit is input.

2. The cutting blade stock apparatus according to claim 1, wherein
the case conveying unit includes a belt conveyor, a case moving part that moves the case placed at the case placement stage to the belt conveyor, a temporary placement region in which the case conveyed by the belt conveyor is temporarily placed, and a case conveying part that conveys the case temporarily placed in the temporary placement region to the shelf.

3. The cutting blade stock apparatus according to claim 2, wherein
the case identification information reading unit is mounted on the case conveying part.

4. The cutting blade stock apparatus according to claim 1, wherein
the cutting blade conveying unit carries in the cutting blade that has been used.

5. The cutting blade stock apparatus according to claim 4, wherein
the cutting blade conveying unit carries in the cutting blade that has been used through a conveyance port.

6. The cutting blade stock apparatus according to claim 5, wherein
the cutting blade conveying unit carries out the specified cutting blade through the conveyance port.

7. The cutting blade stock apparatus according to claim 1, further comprising:
a blade identification information reading unit that reads blade identification information given to the cutting blade.

8. The cutting blade stock apparatus according to claim 1, further comprising:
a plurality of the case placement stages.

9. The cutting blade stock apparatus according to claim 1, wherein
the case is allowed to be placed at an optional position in the case placement stage.

10. The cutting blade stock apparatus according to claim 1, further comprising:
a plurality of dedicated case placement stages at which a predetermined kind of the case is placed; and
a display part, wherein
the display part indicates the dedicated case placement stage at which the case is to be placed on a basis of the case identification information.

11. The cutting blade stock apparatus according to claim 10, wherein
the display part is a display or an indicator light.
